(19) United States
(12) Patent Application Publication
(10) Pub. No.: US 2007/0087514 A1
(43) Pub. Date: Apr. 19, 2007

(54) SOI substrate with selective oxide layer thickness control

(75) Inventor: Takeshi Hamamoto, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/411,828

(22) Filed: Apr. 27, 2006

(30) Foreign Application Priority Data
Apr. 28, 2005 (JP) 2005-133623

(51) Int. Cl. H01L 21/76; H01L 27/12; H01L 27/01; H01L 31/0392

(52) U.S. Cl. 438/406; 257/347

(57) ABSTRACT

A method for forming a SOI substrate device having multiple buried oxide regions comprising the steps of; forming a thin buried oxide layer in a silicon-containing substrate, forming a mask with openings therein on the substrate, implanting oxygen into the substrate through the openings in the mask, forming a buried oxide region in the substrate and a thermal oxide layer at the substrate surface in the mask openings by annealing, exposing the regions of the substrate that were not thermally oxidized by removing the mask, planarizing the crystalline silicon surface of the substrate by thermally oxidizing the substrate surface, removing the oxide layer from the surface of the substrate, exposing a crystalline silicon surface that has no steps between different buried oxide regions of the substrate.

### CROSS-REFERENCE TO RELATED APPLICATIONS

This application is based upon and claims the benefit of priority from the prior Japanese Patent Application No. 2005-133623, filed on Apr. 28, 2005, the entire contents of which are incorporated herein by reference.

### BACKGROUND OF THE INVENTION

1. Field of the Invention

The present invention relates to a semiconductor wafer, semiconductor device, and manufacturing method of a semiconductor device.

2. Description of the Related Art

SOI (Silicon On Insulator) substrates are known to have advantages for building high-speed or low-power devices and for preventing soft errors. System LSI chips, which contain several types of circuits such as digital circuits and analog circuits or memory circuits, are manufactured on partial SOI substrates. The partial SOI substrates are manufactured using the SIMOX (Separation by Implantation of Oxygen) process. Logic devices are manufactured in the SOI regions of the substrate with a buried oxide thickness of 100 to 200 nm and memory circuits, like DRAM, are manufactured in the non-SOI regions.

Recently, FBC (Floating Body Cell) memory devices that do not contain capacitors have been developed on SOI substrates together with logic circuits. The performance of FBC memories improves for thinner buried SOI oxide thicknesses because the signal intensity improves. Due to that, SOI substrates for FBC memories require even thinner oxide layers than do logic circuits.

However, the multi-SIMOX SOI process, which combines several buried oxide layers thicknesses in a single substrate, has problems due to the expansion of the oxide layer volume during annealing. The buried oxide volume change is proportional to the oxide layer thickness. SOI substrates that contain thin and thick buried oxide regions develop steps or bumps at the surface near the region boundaries due to uneven expansion during annealing. Such steps or bumps may reduce device reliability because of increased risk of errors in the lithography process and a smaller margin for the etching process.

Although the problem of surface steps or bumps can be solved by etching the surface of the thicker buried oxide region of a partial SOI substrate during the substrate manufacturing process, it is still difficult to control the thickness of the thinner parts of the buried oxide layer in the multi-SIMOX SOI process. Thus, controlling both the oxide thickness and surface flatness are required for multiple-thickness buried oxide SOI substrates.

### BRIEF SUMMARY OF THE INVENTION

According to a first aspect of the invention, there is provided SOI substrate comprising: a method for forming a SOI substrate device having multiple buried oxide regions comprising the steps of; forming a thin buried oxide layer in a silicon-containing substrate, forming a mask with openings therein on the substrate, implanting oxygen into the substrate through the openings in the mask, forming a buried oxide region in the substrate and a thermal oxide layer at the substrate surface in the mask openings by annealing, exposing the regions of the substrate that were not thermally oxidized by removing the mask, planarizing the crystalline silicon surface of the substrate by thermally oxidizing the substrate surface, removing the oxide layer from the surface of the substrate, exposing a crystalline silicon surface that has no steps between different buried oxide regions of the substrate.

### BRIEF DESCRIPTION OF THE SEVERAL VIEWS OF THE DRAWING

FIG. 1 is a cross-sectional view of a device according to the first and second embodiment of the invention;

FIGS. 2 through 4 are cross-sectional flow diagrams illustrating the manufacturing method of a semiconductor device according to the first embodiment of the invention;

FIGS. 5 through 7 are cross-sectional flow diagrams illustrating the manufacturing method of a semiconductor device according to the second embodiment of the invention;

FIG. 8 is a cross-sectional view of a device according to the second embodiment of the invention;

### DETAILED DESCRIPTION OF THE INVENTION

Some embodiments of the invention are explained below with reference to the drawings. The embodiments, however, should not be construed to limit the invention.

First Embodiment

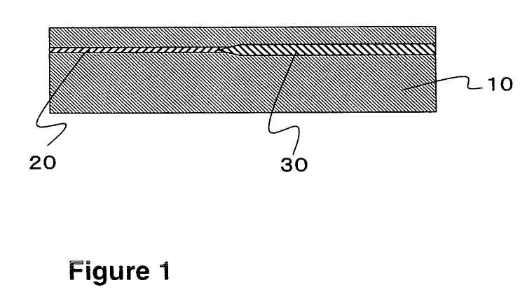

FIG. 1 is a cross-sectional view of a device according to the first embodiment. All of the cross-sectional view is schematic and do not show true relative film thicknesses of actual devices.

The SOI semiconductor substrate comprises a semiconductor bulk 10a 10b, a first thin buried insulating layer 20 formed on a first semiconductor layer, and a second thick buried insulating layer 30 formed on the first semiconductor layer. For example, the thickness of the first buried insulating layer 20 is 10 nm, and the second buried insulating layer 30 is 100 nm thicker than the first insulating layer. The semiconductor bulk 10a, 10b are made of single-crystal silicon, poly-silicon, silicon germanium or silicon carbide. The first buried insulating layer region, for example, can be used for a FBC circuit, and the second buried insulating layer region can be used for a logic circuit. The thicknesses of the first and second buried insulating layers can be adjusted for each circuit type. For example, the thickness of the second buried insulating layer can be varied from 50 nm to 200 nm according to a particular logic circuit generation. If the buried oxide thickness is less than 50 nm, the substrate capacitance can not be neglected and if the thickness is larger than 200 nm, the device performance is degraded by heating of the substrate due to the low thermal conductivity of silicon dioxide. On the other hand, the buried insulating layer has to be thicker than 10 nm for FBC devices. Although thinner buried insulating layers increase signal intensity, the requirement of a thickness of at least 10 nm is set by the need to have sufficient insulation between the top and bottom semiconductor layers.

The depth of the first and second buried insulating layers from the substrate surface is flexible. The depth can be controlled by thinning the surface silicon layer. The depth is optimized for each device type. For example, a 40 nm to 100 nm depth is used for the 45 nm generation logic devices.

The surface of the substrate must be flat and should have no steps due to the different thicknesses of the buried insulating layers in different parts of the substrate. No step means that there are no steps, sharp edges or bumps which may reduce process margins for photo-lithography and etching. The requirement of flatness for the SOI substrate surface becomes progressively more severe for smaller design generations. The difference of the highest and lowest points of a step on the SOI surface must be less than 100 nm for the 130 nm design rule generation and less than 20 nm for 45 nm design rule generation.

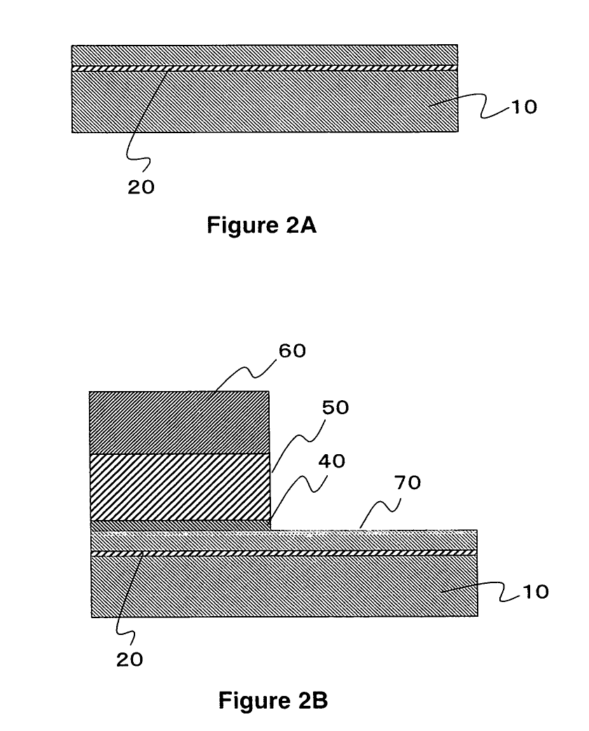

FIGS. 2 through 4 are cross-sectional diagrams showing the flow of the manufacturing process of a semiconductor device according to the first embodiment of the invention. As shown in FIG. 2A, a SOI substrate with a 10 nm buried oxide layer is used. One of the methods of producing such SOI substrates is explained below.

A porous silicon layer is formed on a seed substrate by a nodic oxidation. A single-crystal silicon layer is epitaxially grown on top of the porous silicon layer. Next, an oxide layer is grown on the surface of the single-crystal silicon layer and the surface is attached to a dummy substrate. The two substrates are then separated from each other by cutting at the porous silicon layer and the remaining porous silicon is removed. Finally, the substrate is annealed in hydrogen containing gas to obtain a flat surface.

On an SOI substrate, a first mask 40 and a second mask 50 are deposited sequentially. In this example, the first mask 40 is a 150 nm-thick Si₃N₄ film and the second mask 50 is a 1 μm-thick SiO₂ layer. The first mask should be thick enough to prevent the oxidation of the silicon substrate under the first mask in an annealing process in an oxygen atmosphere. The first and the second mask together should be thick enough to shield the substrate from implanted ions in the ion implantation process at a later stage.

Next, a resist layer is formed on top of the second mask 60 and patterned with normal photo-lithography techniques. The first mask 40 and the second mask 50 are then partially etched by RIE using the resist mask to create region 70. Although in FIG. 2B, the depth of region 70 reaches the substrate, it is not necessary to continue etching until the substrate is reached.

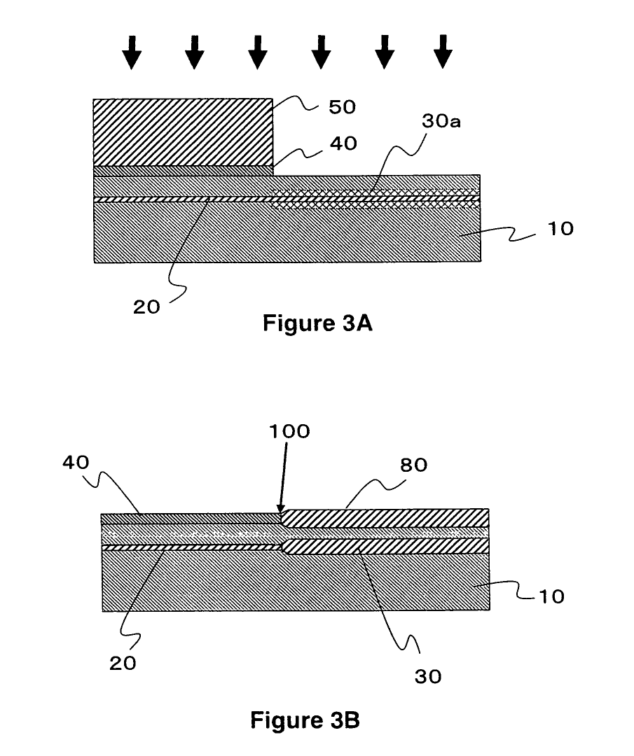

In the next step, oxygen ions are implanted into the substrate through region 70 formed in the first mask 40 and the second mask 50. The ion implantation conditions are, for example, 150 keV to 200 KeV O⁺ions with a total dose of 4×10¹⁷ cm⁻² to 6×10¹⁷ cm⁻². As shown in FIG. 3A, after this process, oxygen ions are implanted into the substrate only in region 70 but not in those parts of the substrate that remain covered by the first mask 40 and the second mask 50.

The second mask 50 is then removed by a selective wet etching process with NH₃F or by dry etching with HF vapor. The substrate is then annealed in an oxygen—containing atmosphere. The first annealing is done, for example, in an atmosphere of Ar gas, mixed with 1% of oxygen, at 1300 to 1400° C. for 4 hours, followed by a second anneal in an atmosphere of 100% oxygen gas at 1300 to 1400° C. for 4 hours. During the first anneal, implanted oxygen reacts with the silicon in the substrate, forming a silicon dioxide layer in the substrate. There should preferably be no oxidation under the first mask region. The conditions for the first anneal are chosen so as to prevent the thin buried oxide layer 20 under the first mask from growing thicker. The first mask 40 must be an oxygen-resistant material or an oxide itself to prevent oxidation under the mask.

The surface area which is not covered by the fist mask will grow an 800 nm-thick first thermal oxide layer 80. Because silicon dioxide has 2.2 times larger volume than crystalline silicon, the thick oxide region 30 will expand and push up the substrate surface. This will create a step 100 between the thin and thick buried oxide regions. The step 100 heights may reach 200 nm.

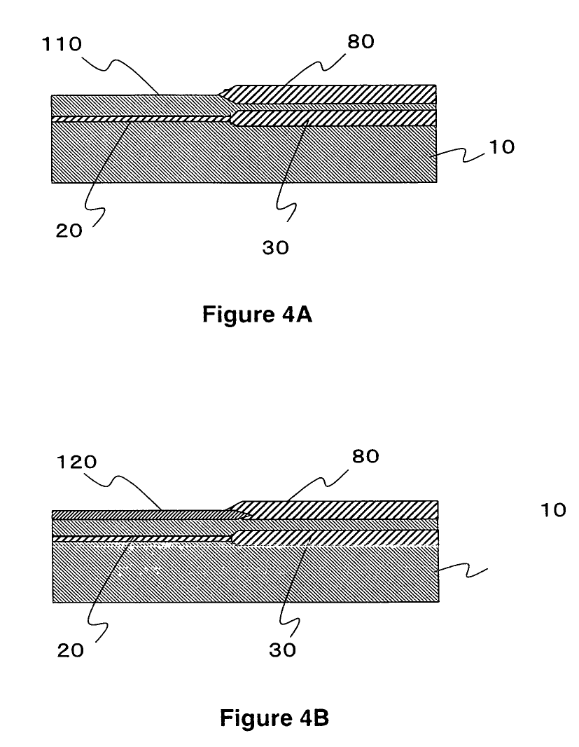

Next, the first mask 40 is removed by wet or dry etching. After this step, the substrate has region 110, with almost no oxide on the surface and region 80 that is covered with an 800 nm-thick oxide layer, as shown in FIG. 4A. The substrate then proceeds to the second annealing step. The conditions for the second anneal are, for example, 100% oxygen atmosphere at 900° C. for 1 hour. During the second annealing process, the surface oxidation rate in region 80, which is already covered with a thick oxide layer, is much slower than in region 110, which is not covered with an oxide. As a result, region 110 is oxidized, forming a second thermal oxide layer 120.

After the annealing procedures, the depth of the oxide-silicon interface is the same in both the first thermal oxide and the second thermal oxide regions. The final surface flatness can be controlled by adjusting the process conditions for the second anneal, as shown in FIG. 4B.

As a last step, the first thermal oxide layer 80 and the second thermal oxide layer 120 are removed by wet or dry etching. An SOI substrate obtained by this process has a flat surface at the boundary between regions of thin and thick buried oxide.

According to embodiment 1, the height difference between the thick and thin buried oxide layers is less than 20 nm and very good control of the thin buried oxide thickness can be achieved even after a thermal oxidation process.

Additional advantages and modifications will readily occur to those skilled in the art. For example, the second mask can be made of Si₃N₄ or other materials.

Second Embodiment

In the first embodiment, the SOI substrate was manufactured by first forming the thinner buried oxide region, followed by the growth of the thicker buried oxide region using a single oxygen implant process. The second embodiment comprises two oxygen implantation processes that are used to produce the thicker and thinner buried SOI substrate regions.

A cross-sectional view of the device according to the second embodiment is the same as for the first embodiment, shown in FIG. 1.

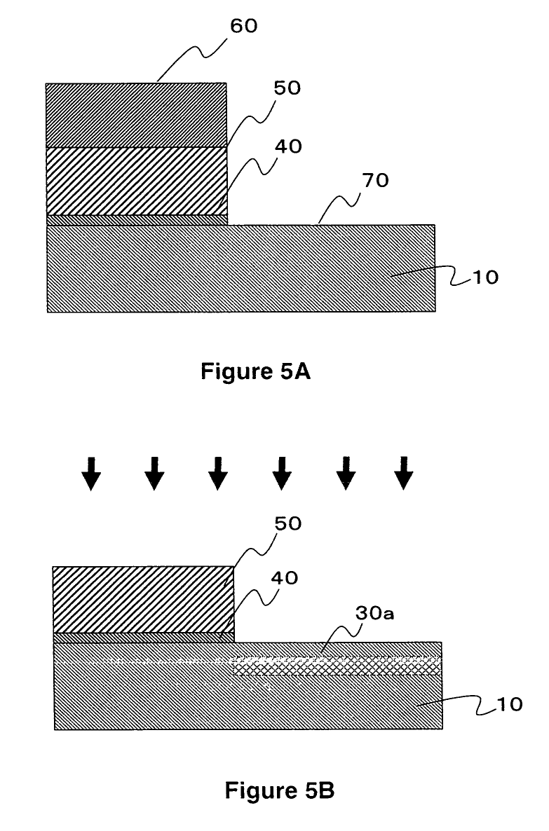

FIGS. 5 through 7 are cross-sectional diagrams showing the flow of the manufacturing process of a semiconductor device according to the second embodiment of the invention. One possible process of producing such a SOI substrate is explained below.

On a bulk substrate 10, a first mask 40 and a second mask 50 are deposited sequentially so that mask 50 covers mask 40. In this example, the first mask 40 is a 150 nm-thick Si₃N₄ film and the second mask 50 is a 1 μm-thick SiO₂ layer. The first mask should be thick enough to prevent oxidation of the silicon substrate under the first mask in an annealing process in an oxygen atmosphere. The first and the second mask together should be thick enough to shield the substrate from implanted ions in the ion implantation process at a later stage.

Next, a resist layer 60 is formed on top of the second mask 50 and patterned with normal photo-lithography techniques. The first mask 40 and the second mask 50 are then partially etched by RIE using the resist mask to create region 70. Although in FIG. 5A, the depth of region 70 reaches the substrate, it is not necessary to continue etching until the substrate is reached.

In the next step, oxygen ions are implanted into the substrate through regions 70 formed in the first mask 40 and the second mask 50 to form the thicker buried oxide layer. The ion implantation conditions are, for example, 180 keV O⁺ions with a total dose of 4×10¹⁷ cm⁻² to 6×10¹⁷ cm⁻². As shown in FIG. 5B, after this process, oxygen ions are implanted into the substrate only in region 70 but not in those parts of the substrate that remain covered by the first mask 40 and the second mask 50.

The second mask 50 is then removed by a selective wet etching process with NH₃F or by dry etching with HF vapor. The substrate is then annealed in an oxygen-containing atmosphere. The first annealing is done, for example, in an atmosphere of Ar gas, mixed with 1% of oxygen, at 1300 to 1400° C. for 4 hours, followed by a second anneal in an atmosphere of 100% oxygen gas at 1300 to 1400° C. for 4 hours. During the first anneal, implanted oxygen reacts with the silicon in the substrate, forming a silicon dioxide layer 30 in the substrate. There should preferably be no oxidation under the first mask region 40. The first mask must be an oxygen-resistant material or an oxide itself to prevent oxidation under the mask.

The surface area which is not covered by the fist mask will grow an 800 nm-thick first thermal oxide layer 80. Because silicon dioxide has 2.2 times larger volume than crystalline silicon, the thick oxide region 30 will expand and push up the substrate surface. This will create a step at the edges of the thick buried oxide regions. The step heights may reach 200 nm.

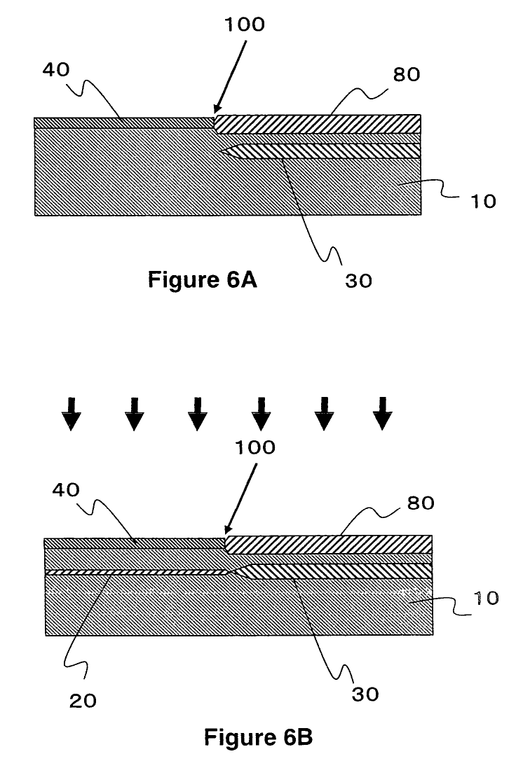

In the next step, oxygen ions are implanted into the substrate through the thin mask 40 and the surface oxide layer 80. The ion implantation conditions are, for example, 180 KeV to 200 keV O⁺ions with a total dose of 1×10¹⁷ cm⁻² to 3×10¹⁷ cm⁻². As shown in FIG. 6B, after this second implantation process, oxygen ions are implanted into the substrate under the first mask region 40 to create a thin buried oxide layer 20. The implantation conditions can be modified to control the thickness and depth of the thin buried oxide layer 20.

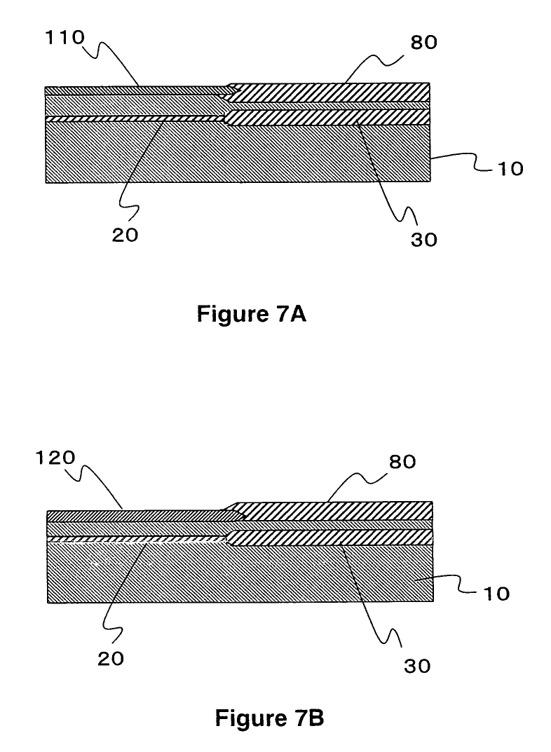

The first mask 40 is then removed by wet or dry etching. After this step, the substrate has a region with almost no oxide on the surface and region 80 that is covered with an 800 nm-thick oxide layer, as shown in FIG. 7A. The substrate then proceeds to the second annealing step. The conditions for the second anneal can be, for example the same as the first annealing conditions. During the second anneal, implanted oxygen reacts with the silicon in the substrate, forming a thin buried silicon dioxide layer 20 in the substrate and also a second oxide layer 110 at the surface which is not covered with an oxide layer.

The substrate then proceeds to the third annealing step. The conditions for the third anneal are, for example, 100% oxygen atmosphere at 900° C. for 1 hour. During the third annealing process, the surface oxidation rate in region 80 is slower than in the second oxide region 110 due to the larger starting thickness of the oxide layer in region 80. As a result, the second oxide in region 110 grows faster than first oxide in the region 80, creating a third oxide layer 120.

After the third annealing procedures, the depth of the oxide-silicon interface is the same in both region 120 and the first oxide region 80, as shown in FIG. 7B. The final surface flatness can be controlled by adjusting the process conditions for the third anneal.

As the last step, the first thermal oxide layer in region 80 and the third oxide layer in region 120 are removed by wet or dry etching. An SOI substrate obtained by this process has a flat surface at the boundary between regions of thin and thick buried oxide.

According to embodiment 2, the height difference between the thick and thin buried oxide layers is less than 20 nm and very good control of the thin buried oxide thickness can be achieved even after the second and third thermal oxidation processes.

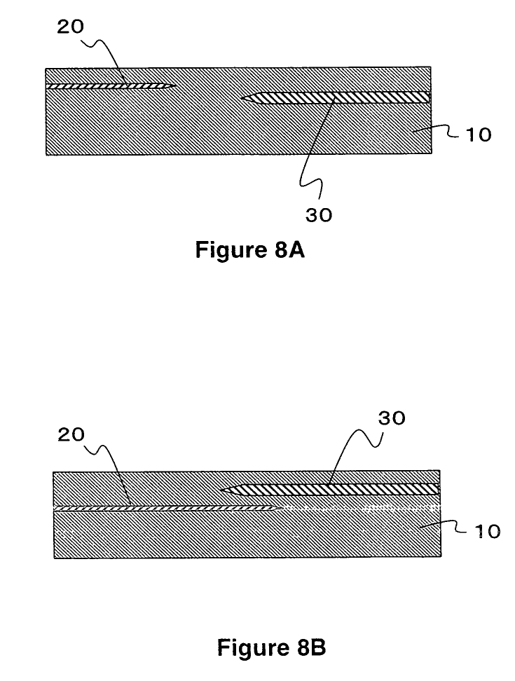

Additional advantages and modifications will readily occur to those skilled in the art. For example, there can be a non-oxide region between the thin buried oxide 20 and thick buried oxide 30, as shown in FIG. 8A or the thin and thick buried oxide regions can overlap, as shown in FIG. 8B. The thin and thick buried oxide layer do not need to be at the same depth from the surface, either can be deeper, as shown in FIGS. 8A and 8B. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for forming a SOI substrate device having multiple buried oxide regions comprising the steps of;
Forming a thin buried oxide layer in a silicon-containing substrate,
forming a mask with openings therein on the substrate,
implanting oxygen into the substrate through the openings in the mask,
forming a buried oxide region in the substrate and a thermal oxide layer at the substrate surface in the mask openings by annealing,
exposing the regions of the substrate that were not thermally oxidized by removing the mask,
planarizing the crystalline silicon surface of the substrate by thermally oxidizing the substrate surface,
removing the oxide layer from the surface of the substrate, exposing a crystalline silicon surface that has no steps between different buried oxide regions of the substrate.

2. The method for forming the SOI substrate device according to claim 1, wherein the height of surface steps is less than 100 nm.

3. The method for forming the SOI substrate device according to claim 1, wherein the height of surface steps is less than 20 nm.

4. The method for forming the SOI substrate device according to claim 1, wherein the device contains a region with a thin buried oxide layer and a region with a thick buried oxide layer.

5. The method for forming the SOI substrate device according to claim 4, wherein the thick buried oxide layer is thicker than 50 nm.

6. The method for forming the SOI substrate device according to claim 4, wherein the thick buried oxide layer thickness is between 50 nm and 200 nm.

7. The method for forming the SOI substrate device according to claim 4, wherein the thinner buried oxide is thicker than 10 nm and thinner than the thick buried oxide layer.

8. The method for forming the SOI substrate device according to claim 1, wherein the mask material is resistant to oxidation.

9. The method for forming the SOI substrate device according to claim 1, wherein the mask is comprised of silicon nitride.

10. A SOI substrate device structure comprising;
a first buried oxide layer region in the substrate, a second buried oxide layer region in the substrate having a smaller buried oxide layer thickness than the buried oxide layer in the first region,
wherein the surface of the substrate at the boundary between the first and second buried oxide regions is flat.

11. The SOI substrate structure according to claim 10, wherein the height of surface steps is less than 100 nm.

12. The SOI substrate structure according to claim 10, wherein the height of surface steps is less than 20 nm.

13. The SOI substrate structure according to claim 10, wherein the first buried oxide layer is thicker than 50 nm.

14. The SOI substrate structure according to claim 10, wherein the first buried oxide layer thickness is between 50 nm and 200 nm.

15. The SOI substrate structure according to claim 10 , wherein the second buried oxide layer is thicker than 10 nm.
